(19) United States
(12) Patent Application Publication
(10) Pub. No.: US 2023/0369159 A1
(43) Pub. Date: Nov. 16, 2023

(54) SEMICONDUCTOR DEVICE

(71) Applicant: WAVEPIA CO., LTD., Gyeonggi-do (KR)

(72) Inventor: Sang Hun LEE, Hwaseong-si (KR)

(73) Assignee: WAVEPIA CO., LTD., Gyeonggi-do (KR)

(21) Appl. No.: 18/333,679

(22) Filed: Jun. 13, 2023

Related U.S. Application Data
(63) Continuation of application No. PCT/KR2022/007764, filed on May 31, 2022.

(30) Foreign Application Priority Data
May 12, 2022 (KR) 10-2022-0058272

(51) Int. Cl. H01L 23/34; H01L 23/367; H01L 23/48; H01L 23/528; H01L 29/20; H01L 29/778

(52) U.S. Cl. CPC H01L 23/34; H01L 23/3677; H01L 23/481; H01L 23/5286; H01L 29/2003; H01L 29/7786

(57) ABSTRACT

The present invention relates to a semiconductor device. The semiconductor device according to an embodiment of the present invention includes a semiconductor substrate, a lower metal layer disposed under the semiconductor substrate and grounded, at least one transistor disposed on an upper portion of the semiconductor substrate, and at least one first through-via configured to pass through the semiconductor substrate and connected to the lower metal layer, wherein the transistor includes a gate electrode, a source electrode, and a drain electrode that are disposed on the semiconductor substrate, an inside of the at least one first through-via is filled with a conductive material, and the conductive material is electrically connected to the lower metal layer, and the at least one first through-via transfers heat generated in the transistor downward from the semiconductor substrate.

### CROSS-REFERENCE TO RELATED APPLICATIONS

This application is a Continuation of International Application No. PCT/KR2022/007764 filed on May 31, 2022, which claims benefit of priority to Korean Patent Application No. 10-2022-0058272 filed May 12, 2022, the entire contents of which are incorporated herein by reference.

### TECHNICAL FIELD

The present invention relates to a semiconductor device, and more specifically, to a semiconductor device capable of measuring the temperature of a transistor.

### BACKGROUND ART

Recently, there has been a growing interest in semiconductor power amplifier (PA) technology or monolithic microwave integrated circuit (MMIC) technology in fields such as electric vehicles, autonomous vehicles, fifth-generation (5G) communication, high-resolution radars, etc.

In particular, various technologies and materials are being developed to transmit or receive data with high output power. For example, gallium nitride (GaN) can be operated at high voltage due to its wide energy gap of 3.4 eV, has high current and power density, and enables high-speed operation, and recently, the use of GaN high electron mobility transistor (HEMT) elements has been rapidly increasing as materials for high-frequency, high-output power, high-efficiency, and small-sized PA elements.

However, as the high frequency, high output power, high efficiency, and miniaturization of semiconductor devices progress, more heat is generated in transistors, and such a phenomenon degrades the performance and lifetime of the semiconductor devices. Therefore, technologies for dissipating heat from semiconductor devices have been actively developed.

However, the conventional semiconductor device is composed of a heat sink, a temperature measurement circuit disposed on an integrated circuit (IC) chip, and the like so that a heat dissipation function and a temperature measurement function are performed by different components. For this reason, conventional semiconductor devices that simultaneously perform a heat dissipation function and a temperature measurement function have a problem that manufacturing costs increase due to a large volume or an additional process required.

Further, the conventional semiconductor devices have a problem that a measured temperature of a heating source is inaccurate because the heat dissipation function and the temperature measurement function are not organically and simultaneously performed.

Further, in the conventional technology for measuring the temperature of a semiconductor device, a temperature sensor is disposed far from a channel region, which is a main heating source, and thus there is a problem that the temperature is not accurately measured.

Further, in the conventional technology for measuring the temperature of a semiconductor device, a temperature sensor is exposed to the air and thus is affected by the air temperature raised while the semiconductor device operates. Therefore, there is a problem that the temperature sensor cannot accurately detect the temperature at the highest heat source of a transistor.

Meanwhile, the above-described related art is technical information that the inventor possessed for derivation of the present invention or acquired in the process of derivation of the present invention, and cannot necessarily be said to be known art disclosed to the general public prior to filing the present invention.
(Document of Related Art) U.S. Pat. No. 9,754,854 (registered on Sep. 5, 2017)

### DISCLOSURE

### Technical Problem

The present invention is directed to providing a semiconductor device in which a component that simultaneously performs a heat dissipation function and a temperature measurement function is disposed in the semiconductor device, thereby increasing space efficiency by reducing a volume of the semiconductor device, and reducing manufacturing costs by reducing processes of manufacturing a semiconductor device.

The present invention is also directed to providing a semiconductor device in which a heat dissipation function and a temperature measurement function of the semiconductor device are organically performed, thereby accurately measuring the temperature of a main heat source of a transistor.

The present invention is also directed to providing a semiconductor device in which a temperature sensor disposed in the semiconductor device is disposed close to a channel region, thereby precisely measuring the temperature of a main heating source of a transistor.

The present invention is also directed to providing a semiconductor device in which a temperature sensor is disposed inside the semiconductor device, thereby measuring the temperature of a heating source without being affected by the temperature of air outside the semiconductor device.

Objects of the present invention are not limited to the above-described objects and other objects that are not described may be clearly understood by those skilled in the art from the following descriptions.

### Technical Solution

One aspect of the present invention provides a semiconductor device which includes a semiconductor substrate, a lower metal layer disposed under the semiconductor substrate and grounded, at least one transistor disposed on an upper portion of the semiconductor substrate, and at least one first through-via configured to pass through the semiconductor substrate and connected to the lower metal layer, wherein the transistor includes a gate electrode, a source electrode, and a drain electrode that are disposed on the semiconductor substrate, an inside of the at least one first through-via is filled with a conductive material, and the conductive material is electrically connected to the lower metal layer, and the at least one first through-via transfers heat generated in the transistor downward from the semiconductor substrate.

The semiconductor device may further include an active layer disposed between the semiconductor substrate and the transistor, wherein the active layer may be made of a compound containing Ga and N.

The at least one first through-via may be formed to pass through the semiconductor substrate under a region in which the at least one transistor is disposed.

The at least one first through-via may be formed to pass through the semiconductor substrate under a region in which the source electrode is disposed and a region from one end of the source electrode to a portion spaced by 5 times a width of the source electrode.

The at least one first through-via may be formed to pass through the semiconductor substrate under the source electrode.

The active layer may include a channel region generated in the active layer when the transistor turns on, and at least one temperature sensor disposed in the active layer and having electrical properties changed according to a temperature of the transistor.

The semiconductor device may further include at least one second through-via configured to pass through the semiconductor substrate under the temperature sensor and connected to the lower metal layer.

The semiconductor device may include at least one metal layer in contact with the at least one temperature sensor, and at least one pad that is disposed on one end of the semiconductor substrate and being in contact with the metal layer, wherein the pad may be electrically connected to the temperature sensor through the metal layer, receive temperature information of the semiconductor device through the metal layer, and transmit the temperature information to a terminal outside the semiconductor device in contact with the pad.

The metal layer may be in contact with the source electrode, and the source electrode may be electrically connected to the pad and the temperature sensor through the metal layer.

### Advantageous Effects

According to any one of the solutions of the present invention, a component that simultaneously performs a heat dissipation function and a temperature measurement function can be disposed in a semiconductor device, thereby increasing space efficiency by reducing a volume of the semiconductor device, and reducing manufacturing costs by reducing processes of manufacturing a semiconductor device.

According to any one of the solutions of the present invention, a heat dissipation function and a temperature measurement function of a semiconductor device can be organically performed, thereby accurately measuring the temperature of a main heat source of a transistor.

According to any one of the solutions of the present invention, a temperature sensor disposed in a semiconductor device can be disposed close to a channel region, thereby precisely measuring the temperature of a main heating source of a transistor.

According to any one of the solutions of the present invention, a temperature sensor can be disposed inside a semiconductor device, thereby measuring the temperature of a heating source without being affected by the temperature of air outside the semiconductor device.

Effects obtainable in the present invention are not limited to the above-described effects and other effects that are not described may be clearly understood by those skilled in the art from the following description.

### DESCRIPTION OF DRAWINGS

FIG. 1 is a plan view of a semiconductor device according to an embodiment of the present invention.

FIG. 2 is a cross-sectional view of the semiconductor device taken along dot-dash line II-IF of FIG. 1.

FIG. 3 is a plan view of a semiconductor device according to another embodiment of the present invention.

FIG. 4 is a cross-sectional view of the semiconductor device taken along dot-dash line IV-IV′ of FIG. 3.

FIG. 5 is a plan view of a semiconductor device according to still another embodiment of the present invention.

FIG. 6 is a cross-sectional view of the semiconductor device taken along dot-dash line VI-VI′ of FIG. 5.

### NODES OF THE INVENTION

Advantages and features of the present invention and methods of achieving the same will be clearly understood with reference to the accompanying drawings and embodiments described in detail below. However, the present invention is not limited to the embodiments to be disclosed below, but may be implemented in various different forms. The embodiments are provided in order to fully explain the present embodiments and fully explain the scope of the present invention for those skilled in the art. The scope of the present invention is only defined by the appended claims.

The shapes, sizes, ratios, angles, numbers, etc. disclosed in the drawings for describing the embodiments of the present invention are only examples, and thus the present invention is not limited to the details shown. Further, in description of the present invention, when it is determined that detailed descriptions of related well-known technology may unnecessarily obscure the gist of the present invention, detailed descriptions thereof will be omitted. When the terms “include,” “have,” and “be made” described in this specification are used, another portion may be added unless the term “only” is used. In the case in which a component is expressed in the singular, the case including the plural is included unless otherwise explicitly stated.

In interpreting components, even when there is no separate explicit description, it is interpreted as including an error range.

It should be understood that, although the terms “first,” “second,” etc. may be used herein to describe various components, these components are not limited by these terms. The terms are only used to distinguish one component from another component. Therefore, it should be understood that a first component to be described below may be a second component within the technical scope of the present invention.

Like reference numerals refer to like components throughout the specification unless otherwise specified.

Features of various embodiments of the present invention may be partially or entirely combined or combined with each other, and as those skilled in the art may fully understand, various interlocking and driving operations are possible technically, and the embodiments may be implemented independently of each other or together in an association relationship.

Hereinafter, the present invention will be described in detail with reference to the accompanying drawings.

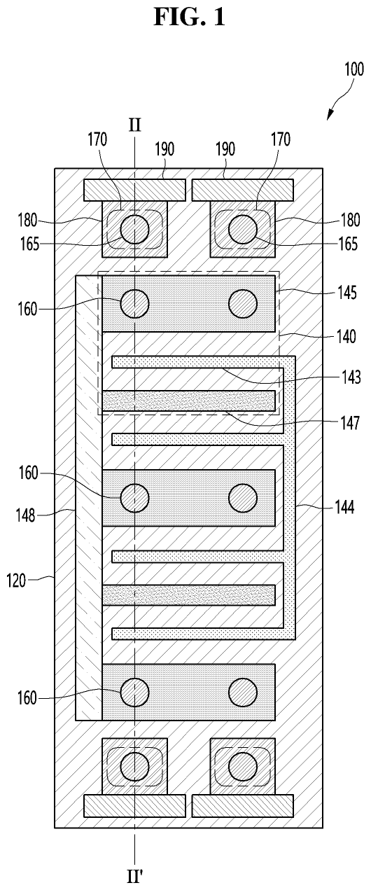

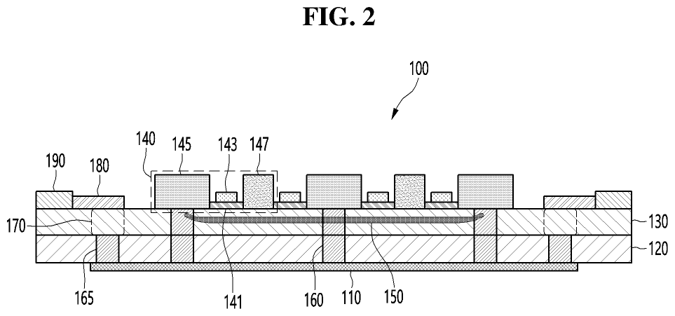

FIG. 1 is a plan view of a semiconductor device according to an embodiment of the present invention, and FIG. 2 is a cross-sectional view of the semiconductor device taken along dot-dash line II-IF of FIG. 1.

First, referring to FIGS. 1 and 2, a semiconductor device 100 includes a lower metal layer 110, a semiconductor substrate 120, at least one transistor 140, and at least one first through-via 160.

Referring to FIG. 1, the at least one transistor 140 is disposed on the center of the semiconductor substrate 120 and includes a source electrode 145 and a drain electrode 147 which are disposed on both sides of a gate electrode 143 with the gate electrode 143 interposed therebetween. A plurality of gate electrodes 143 extend from a gate line 144. A plurality of source electrodes 145 and a plurality of drain electrodes 147 extend from a data line 148. The gate line 144 is disposed in a line shape at one side of the center of the semiconductor device 100, and the data line 148 is disposed in a line shape at the other side of the center of the semiconductor device 100. The gate line 144 and the data line 148 may be disposed in parallel.

The at least one first through-via 160 is disposed in a region in which the source electrode 145 is disposed. At least one second through-via 165 is disposed in a region in which a temperature sensor 170 is disposed. At least one temperature sensor 170 is disposed to be spaced a predetermined distance from the transistor 140. Further, the temperature sensor 170 may be disposed to cover a region in which the second through-via 165 is disposed. At least one metal layer 180 is disposed to include a region in which the temperature sensor 170 is disposed, and is in contact with a pad 190. At least one pad 190 is disposed on an outer side of the semiconductor substrate.

Referring to FIG. 2, the lower metal layer 110 is disposed in a line shape under the semiconductor substrate 120, the semiconductor substrate 120 is disposed on the lower metal layer 110, and an active layer 130 is disposed on the semiconductor substrate 120. The at least one transistor 140 is disposed on the active layer 130 and disposed between the pads 190 that are disposed at both sides of the semiconductor substrate 120. An oxide layer 141 is disposed between the active layer 130 and the gate electrode 143. The gate electrode 143 is disposed on the oxide layer 141. The source electrode 145 and the drain electrode 147 are disposed on the active layer 130 and disposed on side surfaces of the oxide layer 141. A channel region 150 is generated inside the active layer 130 and generated below the at least one transistor 140.

The first through-via 160 is disposed to have a vertical structure that extends from a lower portion of the source electrode 145 to the lower metal layer 110 and passes through the semiconductor substrate 120 and the active layer 130. The second through-via 165 is disposed to have a vertical structure that extends from a lower portion of the temperature sensor 170 to the lower metal layer 110 and passes through the semiconductor substrate 120. The temperature sensor 170 is disposed inside the active layer 130 on an outer side of the semiconductor device 100. The metal layer 180 is disposed on the active layer 130 and disposed to cover the temperature sensor 170. The pads 190 may be disposed on the active layer 130 and disposed on both ends of the semiconductor device 100.

Referring to FIG. 2, the lower metal layer 110 is disposed on a partial region of a lower portion of the semiconductor substrate 120. The lower metal layer 110 includes a metal and may be made of a material having high electrical conductivity, such as gold (Au). The lower metal layer 110 is grounded and is electrically connected to at least one component of the semiconductor device 100. Preferably, the lower metal layer 110 may be electrically connected to the source electrode 145 and the temperature sensor 170.

Referring to FIGS. 1 and 2, the semiconductor substrate 120 is disposed between the lower metal layer 110 and the active layer 130. The semiconductor substrate 120 may be made of one of various materials such as Si, SiC, Al₂O₃, GaAs, InP, InAs, InSb, and the like. An oxide dielectric layer may be disposed inside the semiconductor substrate 120. Further, the semiconductor substrate 120 may be generated through processes such as oxidation, photographing, etching, and thin film forming processes.

Referring to FIG. 2, the active layer 130 is disposed on the semiconductor substrate 120. Further, the temperature sensor 170 may be disposed inside the active layer 130, and the transistor 140, the metal layer 180, and the pads 190 may be disposed on the active layer 130.

The active layer 130 may be made of one of various materials according to the types of the semiconductor substrate 120 and the transistor 140. The active layer 130 may be generated through an epitaxial growth process or the like, in which Ga, which is a Group 3 element, and N, which is a Group 5 element, are supplied to the semiconductor substrate 120. Accordingly, the material of the active layer 130 may be a compound containing of Groups 3 and 5 elements. For example, the material of the active layer 130 may be AlGaN, GaN, or GaAs. The active layer 130 has thermal conductivity and may transfer heat of the channel region 150 to the temperature sensor 170.

Referring to FIGS. 1 and 2, the transistor 140 may be disposed on the active layer 130 and disposed to be surrounded by a plurality of pads 190. The transistor 140 includes the oxide layer 141, the gate electrode 143, the source electrode 145, and the drain electrode 147. The arrangement and structure of the transistors 140 are illustrated and described as a structure of a metal-oxide-semiconductor field-effect transistor (MOSFET) for convenience of description, but the present invention is not limited thereto, and the arrangement and structure of the transistor 140 may be replaced with one of various arrangements and structures of transistors. For example, the transistor 140 may be disposed within a predetermined region on the semiconductor substrate 120, and may have a structure of a high electron mobility transistor (HEMT) or a structure divided into an upper electrode and a lower electrode. The transistor 140 may adjust a current or voltage flow to amplify a signal, or perform a current switch function.

Further, a transistor array is an array in which a plurality of transistors 140 are disposed in the semiconductor device 100 at regular intervals or in a regular manner. Specifically, a plurality of gate electrodes 143 extending from a gate line 144 and a plurality of source electrodes 145 and a plurality of drain electrodes 147 extending from a data line 148 are alternately disposed in parallel, the plurality of transistors 140 are disposed adjacent to each other at regular intervals, and thus a transistor array may be generated. In FIGS. 1 and 2, 3 to 4 transistors 140 are disposed on the center of the semiconductor device 100 to form a transistor array.

Since the gate line 144 and the data line 148 are merely lines for efficiently forming the plurality of transistors 140, the gate line 144 and the data line 148 may be freely disposed according to the characteristics and configuration of a target semiconductor device.

The plurality of transistors 140 may be designed to have the same electrical properties, and the number of the plurality of transistors 140 and the width and length of each electrode may be arbitrarily designed. For example, in the case of a configuration in which the first through-via 160 is disposed under the source electrode 145, the width of the source electrode 145 may be increased to allow the channel region 150 to be in contact with an upper portion of the first through-via 160.

Further, when a current flowing between a source electrode and a drain electrode of any one transistor 140 among the plurality of transistors 140 is smaller than a current flowing between a source electrode and a drain electrode of each of the remaining transistors 140, the plurality of transistors 140 may be disposed by decreasing or increasing the width and length of the electrode of the any one transistor 140.

Referring to FIG. 2, the oxide layer 141 is disposed on the active layer 130 and is disposed below the gate electrode 143 and between the source electrode 145 and the drain electrode 147. The semiconductor substrate 120 may be formed through a discretization process and may be made of an oxide. Preferably, the oxide layer 141 may be made of SiO₂. The oxide layer 141 functions as a gate insulator that prevents a current from flowing between the gate electrode 143 and the channel region 150. However, since the layout of the oxide layer 141 such as horizontal or vertical arrangement and the performance of the function such as insulation or dielectric function vary according to the forming process of the semiconductor device 100, the present invention is not limited to the arrangement or function of the embodiment.

Referring to FIG. 2, the gate electrode 143 may be made of polycrystalline silicon deposited and disposed on the oxide layer 141. The gate electrode 143 may be insulated by the oxide layer 141 disposed between the active layer 130 and the gate electrode 143. When a voltage is applied to the gate electrode 143, the gate electrode 143 may adjust electrical conductivity of the channel region 150.

Referring to FIG. 2, the source electrode 145 and the drain electrode 147 are disposed on the active layer 130. The source electrode 145 and the drain electrode 147 are disposed on the active layer 130 to be spaced apart from the gate electrode 143 with the gate electrode 143 interposed therebetween.

The source electrode 145 and the drain electrode 147 may be made of the same material. Specifically, the source electrode 145 and the drain electrode 147 may be made of a metal. Accordingly, the source electrode 145 and the drain electrode 147 may be in ohmic contact with the active layer 130 which is a semiconductor. Further, since the source electrode 145 and the drain electrode 147 are symmetrical elements, the transistor 140 may be normally operated even when positions of the source electrode 145 and the drain electrode 147 are switched. When a voltage is applied between the source electrode 145 and the drain electrode 147, a drain current flows, and the drain current may be controlled by a voltage applied between the gate electrode 143 and the source electrode 145. In the above case, a linear relationship may be formed between the voltage and the current applied to the drain electrode 147, and in this case, the source electrode 145 and the drain electrode 147 may be operated like variable resistors. The source electrode 145 serves to supply charge carriers to the channel region 150, and the drain electrode 147 serves to absorb the charge carriers.

The channel region 150 is a region through which carriers such as electrons or holes can move in the transistor 140. Referring to FIGS. 1 and 2, the channel region 150 is generated under the transistor 140. Specifically, the channel region 150 is generated between the active layer 130 under the source electrode 145 and the active layer 130 under the drain electrode 147.

The channel region 150 is generated by an electric field formed by applying the voltage to the gate electrode 143. Specifically, the channel region 150 may be generated by moving the electrons or holes in a partial region of the active layer 130 when a voltage higher than a threshold voltage is applied to the gate electrode 143 and a voltage is applied to the drain electrode 147. Thereafter, as the voltage applied to the gate electrode 143 increases, the concentration of the carriers of the channel region 150 increases, and thus electrical conductivity may increase. The channel region 150 has conductivity and constant resistance.

Generally, since a change in electric potential generated when a voltage is applied to the gate electrode 143 or the supply of the voltage is stopped causes the most heat energy to be generated in the transistor 140, a region of the channel region 150 close to the gate electrode 143 may be a portion in the semiconductor device 100 having the highest temperature.

Referring to FIGS. 1 and 2, each of the plurality of first through-vias 160 may be disposed to have a vertical structure that extends from a lower portion of a region in which the transistor 140 is disposed to the lower metal layer 110 and passes through the semiconductor substrate 120 and the active layer 130. Such a structure may be understood as a through-silicon via (TSV). Preferably, each of the plurality of first through-vias 160 may be disposed to extend from the region in which the source electrode 145 is disposed and from a lower portion of a region from one end of the source electrode 145 to a portion spaced by 5 times the width of the source electrode 145 to the lower metal layer 110 to pass through the semiconductor substrate 120 and the active layer 130.

In order for the transistor 140 to operate, one of the components of the transistor 140 should be grounded, and more preferably, the first through-via 160 may pass through the semiconductor substrate 120 and the active layer 130 under the source electrode 145. In this case, the first through-via 160 passing through the semiconductor substrate 120 and the active layer 130 under the source electrode 145 may be understood as an inside source via (ISV).

An inside of the first through-via 160 is filled with a conductive material, and the conductive material is electrically connected to the lower metal layer 110. Here, the conductive material may be a material having high electrical conductivity such as gold (Au) or copper (Cu). Further, the first through-via 160 may allow, in a semiconductor chip having a structure in which a plurality of semiconductor devices 100 are stacked, elements of one semiconductor device 100 to be electrically connected to elements of another semiconductor device. Specifically, since the first through-via 160 electrically connects the lower metal layer 110 in contact with the conductive material with which the inside of the first through-via 160 is filled to the source electrode 145 of the transistor 140, the source electrode 145 may be grounded. In such a connection method, space consumption and process costs can be reduced and a signal transmission speed and power consumption can be improved, as compared to a wire bonding method in which a wire should extend to the outside of the semiconductor in a semiconductor chip having a stacked structure device 100.

Further, since the first through-via 160 is in contact with the source electrode 145 and the channel region 150 and is filled with a material having thermal conductivity, heat generated by the operation of the transistor 140 may be transferred downward from the semiconductor substrate 120.

Meanwhile, two first through-vias 160 are disposed for each source electrode 145 and disposed in a vertical structure, but this is for convenience of description, and the arrangement position, number, and arrangement structure of the first through-vias 160 may be determined in various ways in consideration of the size of the semiconductor device 100, the arrangement of the transistors 140 and their electrodes, and the heat generation levels of the semiconductor device 100 and the transistor 140.

Referring to FIGS. 1 and 2, each of the plurality of second through-vias 165 is disposed to have a vertical structure that extends from the lower portion of the temperature sensor 170 to the lower metal layer 110 and passes through the semiconductor substrate 120.

An inside of the second through-via 165 is filled with a conductive material, and the conductive material is electrically connected to the lower metal layer 110. Here, the conductive material may be the same material as the material with which the inside of the first through-via 160 is filled. That is, the conductive material of the inside of the second through-via 165 may be a material having high electrical conductivity such as gold (Au) or copper (Cu). Further, the second through-via 165 electrically connects the lower metal layer 110 in contact with the conductive material with which the inside of the second through-via 165 is filled to the temperature sensor 170. Furthermore, the second through-via 165 may be electrically connected to the metal layer 180 in contact with the temperature sensor 170, and the pad 190. Accordingly, the second through-via 165 may electrically connect the temperature sensor 170 to the lower metal layer 110 to ground the temperature sensor 170. In order to measure the voltage or current of the temperature sensor 170 at an outside of the semiconductor device 100, a measurement terminal should apply a voltage or current to the temperature sensor 170. However, when the temperature sensor 170 is in a grounded state, only one measurement terminal in contact with the pad 190 is required, and thus costs or a configuration required to measure the temperature of a main heating source in the semiconductor device 100 can be reduced.

Since the second through-via 165 and the first through-via 160 are similar except for arrangement positions and connection relationships, the second through-via 165 and the first through-via 160 may be simultaneously formed in the same process. That is, the second through-via 165 may be made of substantially the same material as the first through-via 160 and may be formed through the same process. Accordingly, the manufacturing process of the semiconductor device 100 can be rapidly performed and the manufacturing costs can be reduced.

Referring to FIGS. 1 and 2, the temperature sensor 170 is disposed in the active layer 130 and is disposed between the region in which the transistor 140 is disposed and the region in which the pad is disposed. Further, the lower portion of the temperature sensor 170 is in contact with the second through-via 165 and an upper portion of the temperature sensor 170 is in contact with the metal layer 180. The temperature sensor 170 may be isolated from air outside the semiconductor device 100 due to the metal layer 180. Accordingly, the temperature sensor 170 may detect a change in temperature of an inside of the semiconductor device 100 without detecting a change in temperature of the outside of the semiconductor device 100. Specifically, the temperature sensor 170 may detect the change in temperature of the inside of the semiconductor device 100 by detecting heat transferred through the active layer 130. More specifically, the heat generated in the transistor 140 may be transferred through the active layer 130, and the temperature sensor 170 may detect the heat transferred through the active layer 130 to detect the degree of the heat generated in the transistor 140, which is a main heating source of the inside of the semiconductor device 100, and measure the change in temperature.

Further, the temperature sensor 170 may additionally receive the heat generated in the transistor 140 through the first through-via 160, the lower metal layer 110, and the second through-via 165. Therefore, the temperature sensor 170 may measure the change in temperature in more detail using the degree of a change in electrical conductivity and thermal conductivity of the material filling the second through-via 165 caused by the heat generated in the transistor 140.

When the temperature sensor 170 is spaced a predetermined distance or more from the transistor 140, the semiconductor device 100 is easily manufactured and the temperature sensor 170 does not degrade the radio frequency (RF) characteristics of the semiconductor device 100. In addition, the temperature sensor 170 needs to be in close contact with the transistor 140 to some extent to accurately measure the temperature of the main heat source of the transistor 140.

Therefore, the temperature sensor 170 may be disposed to be spaced apart from the source electrode 145 by 0.5 to 5 times the width of the source electrode 145. Preferably, the temperature sensor 170 may be disposed to be spaced apart from the source electrode 145 by 0.9 to 1.1 times the width of the source electrode 145. More preferably, the temperature sensor 170 may be disposed to be spaced apart from the source electrode 145 by the width of the source electrode 145.

Since the temperature sensor 170 is formed to be inserted into the active layer 130 in the process of forming the active layer 130, the number of additional processes required to place the temperature sensor 170 on the semiconductor device 100 is reduced. Therefore, the required time or manufacturing costs of manufacturing the semiconductor device 100 including the temperature sensor for measuring the temperature of the inside of the semiconductor device 100 can be reduced.

The temperature sensor 170 may be made of a material whose electrical properties are changed according to temperature. The temperature sensor 170 may be a p-n junction diode whose output voltage is changed according to the temperature of a junction, and may be another transistor different from the transistor 140, which is the main heating source in the semiconductor device. Preferably, the temperature sensor 170 may be a thermo-variable resistor or thermo-variable capacitor whose resistance value is changed according to temperature. In this case, the temperature sensor 170 may be disposed inside the active layer 130 with less process and costs than a diode or transistor, and a space occupied by the temperature sensor 170 may also be narrow.

The temperature sensor 170 composed of a thermo-variable resistor may be made of one of various materials. The temperature sensor 170 may be a thin film resistor (TFR) and may be made of NiCr or TaN. Preferably, the temperature sensor 170 may be a Mesa resistor. Generally, since a Mesa resistor has a high temperature coefficient of resistivity (TCR), the temperature sensor 170 composed of the Mesa resistor may accurately and rapidly measure a change in temperature of the transistor 140.

Referring to FIGS. 1 and 2, the metal layer 180 is disposed on a partial region of the active layer 130. Specifically, the metal layer 180 is disposed on an upper region of the temperature sensor 170 and is disposed in contact with the pad 190. The metal layer 180 may be disposed to partially or entirely cover the temperature sensor 170. The metal layer 180 may be a portion of a barrier metal deposited to prevent contamination of the semiconductor device 100.

The metal layer 180 allows the temperature sensor 170 and the pad 190 to be electrically connected to or be in contact with each other.

Further, the metal layer 180 may be formed to have thermal conductivity much lower than the thermal conductivity of the active layer 130, and disposed to cover the temperature sensor 170. According to the above configuration and arrangement, the temperature sensor 170 is isolated from the air outside the semiconductor device 100 due to the metal layer 180, and a change in electrical properties of the temperature sensor 170 may depend more on a change in temperature of the heating source of the channel region 150 than that in temperature of external air heated by the operation of the transistor 140. Accordingly, the temperature sensor 170 may accurately and precisely measure the temperature at the highest heating source of the transistor 140.

The pad 190 is a portion through which a measurement terminal outside the semiconductor device 100 is electrically connected to the semiconductor device 100. Referring to FIG. 1, the pad 190 is disposed on one end of the semiconductor device 100 to surround the transistor 140. Further, the pad is disposed on the active layer 130. The pad 190 is made of a metal and transmits information about the temperature and RF characteristics of the semiconductor device 100 to the outside of the semiconductor device 100. Further, the pad 190 may receive various electrical signals supplied from the outside of the semiconductor device 100 and supply the received electrical signals to the semiconductor device 100.

The pad 190 may be electrically connected to the temperature sensor 170 through the metal layer 180 so that temperature information of the semiconductor device 100 may be received from the metal layer 180. Here, the temperature information of the semiconductor device 100 refers to the electrical properties of the temperature sensor 170 that are changed according to heat generated in the semiconductor device 100. For example, the temperature information of the semiconductor device 100 may be resistance or capacitance of the temperature sensor 170 that are changed due to the heat generated in the transistor 140.

Accordingly, the measurement terminal outside the semiconductor device 100 is in contact with the pad 190 and applies a current to the temperature sensor 170 to measure the voltage of the temperature sensor 170 or measure the resistance of the temperature sensor 170, and thus the temperature information of the semiconductor device 100 may be received as an electrical signal through a change in resistance or capacitance of the temperature sensor 170. Therefore, when the temperature sensor 170 is connected to the lower metal layer 110 through the second through-via 165, the lower metal layer 110 is grounded so that a measurement terminal connected to a ground electrode is unnecessary, and thus the temperature information of the semiconductor device 100 may be transmitted to the outside of the semiconductor device 100 using only one measurement terminal connected to the pad 190.

The arrangement, number, or shape of the pads 190 is not limited to the arrangement, number, or shape in FIGS. 1 and 2, and the pads 190 may be disposed in consideration of the positions at which the pads 190 are in contact with the measurement terminal, and distances from and connection relationships with the temperature sensor 170. As the arrangement of the pads 190 and the temperature sensor 170 becomes closer, the heat of the channel region 150 may be transferred to the temperature sensor 170 without loss, and thus the temperature sensor 170 may accurately and precisely measure the temperature of the channel region 150, which is the main heat source.

According to the above-described embodiment, since the inside of the first through-via 160 filled with the material having thermal conductivity is disposed to extent from the region in which the transistor 140 is disposed to the lower metal layer 110 to pass through the semiconductor substrate 120 and the active layer 130, the semiconductor device 100 may transfer the heat generated in the transistor 140 downward from the semiconductor substrate 120.

According to the above-described embodiment, the first through-via 160 may transfer the heat generated by the operation of the transistor 140 downward from the semiconductor substrate 120, the second through-via 165 may electrically connect the temperature sensor 170 and the lower metal layer 110 to reduce the costs of measuring the temperature, and the first through-via 160 and the second through-via 165 may be simultaneously formed in the same process. Therefore, the semiconductor device 100 may be rapidly manufactured at low costs despite including components required for a heat dissipation function and the temperature measurement function.

According to the above-described embodiment, the temperature sensor 170 may be spaced an appropriate interval from the transistor 140 so that the semiconductor device 100 is easily manufactured and the temperature sensor 170 does not degrade the RF characteristics of the semiconductor device 100, and the temperature sensor 170 may accurately measure the temperature of the main heating source of the transistor 140 through the active layer 130 having thermal conductivity and the second through-via 165.

According to the above-described embodiment, the temperature sensor 170 is formed to be inserted into the active layer 130 in the process of forming the active layer 130, and thus there are few additional processes required to place the temperature sensor 170 on the semiconductor device 100. Therefore, the time required for the manufacturing process or the manufacturing costs can be reduced.

According to the above-described embodiment, the temperature sensor 170 is isolated from the air outside the semiconductor device 100 by the metal layer 180, a change in electrical properties of the temperature sensor 170 depends more on the change in temperature of the heating source of the channel region 150, and thus the temperature sensor 170 may accurately and precisely measure the temperature at the highest heating source of the transistor 140 without being affected by the change in temperature of the air outside the semiconductor device 100 heated by the operation of the transistor 140.

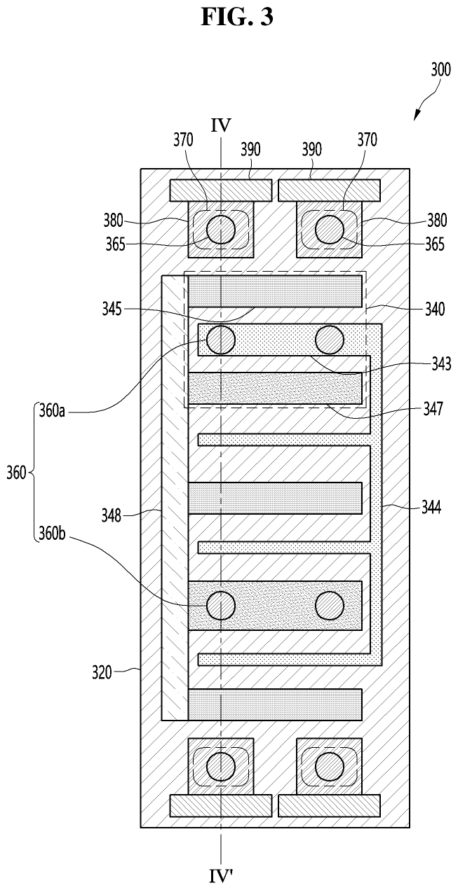

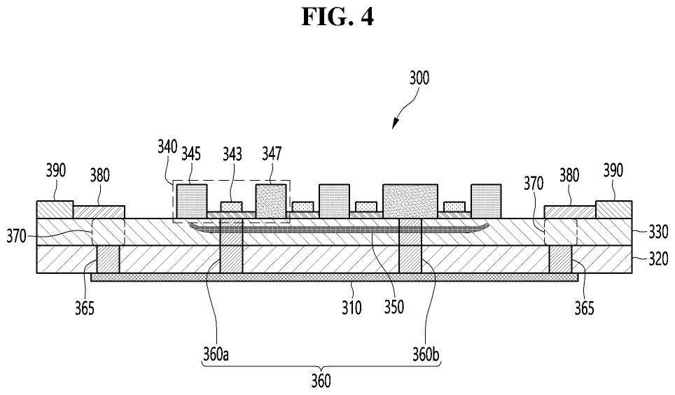

FIG. 3 is a plan view of a semiconductor device according to another embodiment of the present invention, and FIG. 4 is a cross-sectional view of the semiconductor device taken along dot-dash line IV-IV′ of FIG. 3. When some components of the present embodiment overlap with some components of another embodiment described above, descriptions of the components will not be repeated.

Referring to FIGS. 3 and 4, a semiconductor device 300 includes a lower metal layer 310, a semiconductor substrate 320, at least one transistor 340, and at least one first through-via 360.

Referring to FIGS. 3 and 4, a first gate through-via 360a is formed under a gate electrode 343 to vertically pass through the semiconductor substrate 320 and the active layer 330, and a first drain through-via 360b is formed under a drain electrode 347 to vertically pass through the semiconductor substrate 320 and the active layer 330. The first through-via 360 passing through the semiconductor substrate 320 and the active layer 330 under a region other than a source electrode 345 among regions in which the transistors 340 are disposed may be understood as an outside source via (OSV).

According to the above-described embodiment, the semiconductor device 300 having a heat dissipation function and a temperature measurement function while grounding the gate electrode 343 or the drain electrode 345 may be manufactured.

According to the above-described embodiment, generally, a channel region 350 close to the gate electrode 343 is a region having the highest temperature in the semiconductor device 300, and thus the first gate through-via 360a that is formed under the gate electrode 343 to pass through the semiconductor substrate 320 and the active layer 330 can rapidly transfer heat of the gate electrode 343 downward and, at the same time, the highest temperature of the semiconductor device 300 can be measured more precisely.

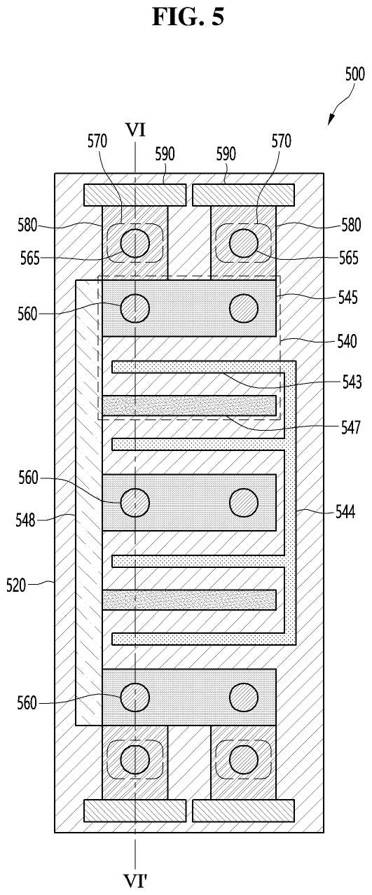

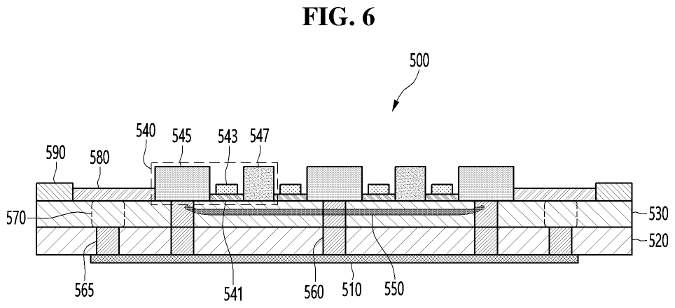

FIG. 5 is a plan view of a semiconductor device according to still another embodiment of the present invention, and FIG. 6 is a cross-sectional view of the semiconductor device taken along dot-dash line VI-VI′ of FIG. 5. When some components of the present embodiment overlap with some components of another embodiment described above, descriptions of the components will not be repeated.

Referring to FIGS. 5 and 6, a semiconductor device 500 includes a lower metal layer 510, a semiconductor substrate 520, at least one transistor 540, and at least one first through-via 560.

Referring to FIGS. 5 and 6, a metal layer 580 is disposed on a partial region on an active layer 530. Specifically, the metal layer 580 is disposed above a region in which a temperature sensor 570 is disposed. Preferably, the metal layer 580 may be disposed to fully cover an upper portion of the temperature sensor 570.

Further, the metal layer 580 not only allows the temperature sensor 570 and a pad 590 to be in contact with each other but also allows a source electrode 545 and the temperature sensor 570 to be in contact with each other. Accordingly, the source electrode 545, the temperature sensor 570, and the pad 590 may be electrically and thermally connected to each other through the metal layer 580. Therefore, the temperature sensor 570 may detect heat that is generated in the transistor 540 and transferred through the active layer 530, and, at the same time, may also detect the heat generated in the transistor 540 through the first through-via 560, the metal layer 580, and a second through-via 565. Accordingly, the semiconductor device 500 according to the embodiment of the present invention can more rapidly and accurately detect and measure the heat generated in the transistor 540 through the temperature sensor 570.

Furthermore, the temperature sensor 570 may receive temperature information generated in the source electrode 545 as well as a channel region 550 through the first through-via 560, the metal layer 580, and the second through-via 565 that are connected to the source electrode 545.

According to the above-described embodiment, the temperature sensor 570 may receive temperature information such as the voltage, resistance, and capacitance of the source electrode 545 as well as the channel region 550, and thus the temperature sensor 570 can more rapidly and accurately measure the temperature of the transistor 540.

Although embodiments of the present invention have been described in more detail with reference to the accompanying drawings, the present invention is not necessarily limited to these embodiments, and may be variously modified and implemented without departing from the technical spirit of the present invention. Therefore, the embodiments disclosed in the present invention should be considered in a descriptive sense only and not for purposes of limitation. Accordingly, the scope of the present invention is not limited by the embodiments. Therefore, the above-described embodiments should be considered in a descriptive sense only and not for purposes of limitation. The scope of the present invention should be interpreted by the appended claims and encompasses all modifications and equivalents that fall within the scope of the appended claims.

1. A semiconductor device comprising:
a semiconductor substrate;
a lower metal layer disposed under the semiconductor substrate and grounded;
at least one transistor disposed on an upper portion of the semiconductor substrate; and
at least one first through-via configured to pass through the semiconductor substrate and connected to the lower metal layer,
wherein the transistor includes a gate electrode, a source electrode, and a drain electrode that are disposed on the semiconductor substrate,
an inside of the at least one first through-via is filled with a conductive material, and the conductive material is electrically connected to the lower metal layer, and
the at least one first through-via transfers heat generated in the transistor downward from the semiconductor substrate.

2. The semiconductor device of claim 1, further comprising an active layer disposed between the semiconductor substrate and the transistor,
wherein the active layer is made of a compound containing Ga and N.

3. The semiconductor device of claim 2, wherein the at least one first through-via is formed to pass through the semiconductor substrate under a region in which the at least one transistor is disposed.

4. The semiconductor device of claim 3, wherein the at least one first through-via is formed to pass through the semiconductor substrate under a region in which the source electrode is disposed and a region from one end of the source electrode to a portion spaced by 5 times a width of the source electrode.

5. The semiconductor device of claim 4, wherein the at least one first through-via is formed to pass through the semiconductor substrate under the source electrode.

6. The semiconductor device of claim 2, wherein the active layer includes:
a channel region generated in the active layer when the transistor turns on; and
at least one temperature sensor disposed in the active layer and having electrical properties changed according to a temperature of the transistor.

7. The semiconductor device of claim 6, further comprising at least one second through-via configured to pass through the semiconductor substrate under the temperature sensor and connected to the lower metal layer.

8. The semiconductor device of claim 6, comprising:
at least one metal layer in contact with the at least one temperature sensor; and
at least one pad that is disposed on one end of the semiconductor substrate and being in contact with the metal layer,
wherein the pad is electrically connected to the temperature sensor through the metal layer, receives temperature information of the semiconductor device through the metal layer, and transmits the temperature information to a terminal outside the semiconductor device in contact with the pad.

9. The semiconductor device of claim 8, wherein the metal layer is in contact with the source electrode, and
the source electrode is electrically connected to the pad and the temperature sensor through the metal layer.
